(19) United States
(12) Patent Application Publication
(10) Pub. No.: US 2013/0185608 A1
(43) Pub. Date: Jul. 18, 2013

(54) SCAN CHAIN ACCESS IN 3D STACKED INTEGRATED CIRCUITS

(71) Applicant: Sudipta Bhawmik, Bridgewater, NJ (US)

(72) Inventor: Sudipta Bhawmik, Bridgewater, NJ (US)

(73) Assignee: QUALCOMM Incorporated, San Diego, CA (US)

(21) Appl. No.: 13/420,099

(22) Filed: Mar. 14, 2012

Related U.S. Application Data
(60) Provisional application No. 61/587,882, filed on Jan. 18, 2012.

(51) Int. Cl. G01R 31/3177

(52) U.S. Cl. 714/727; 714/E11.155

(57) ABSTRACT

Stacked integrated circuits (ICs) having a base component and secondary component are tested. The base component has a scan input pad, a scan output pad, a base scan chain, and a base chain access block including a base chain select multiplexor and a base bypass multiplexor. The secondary component has a secondary scan chain and a secondary chain access block including a secondary chain select multiplexor and a secondary bypass multiplexor. The secondary chain select multiplexor is configured to receive input directly from the base component and another component. The base and secondary chain access blocks are configured to selectively access the base scan chain and/or the secondary scan chain.

### CROSS-REFERENCE TO RELATED APPLICATION(S)

This application claims the benefit of U.S. Provisional Application No. 61/587,882, entitled “SCAN CHAIN ACCESS IN 3D STACKED INTEGRATED CIRCUITS” and filed on Jan. 18, 2012, the disclosure of which is expressly incorporated by reference herein in its entirety.

### BACKGROUND

1. Field

The present disclosure generally relates to semiconductor device assembly and testing. More specifically, the present disclosure relates to testing stacked integrated circuits (ICs).

2. Background

Current technology employs stacked semiconductor chips (e.g., microprocessors, digital signal processors, etc.) A 3D semiconductor device (or stacked IC device) can contain two or more semiconductor devices stacked vertically so they occupy less space than two or more conventionally arranged semiconductor devices. Each IC tier may include functional blocks such as logic, memory and analog blocks. The stacked IC device operates as a single integrated circuit built by stacking silicon wafers and/or ICs and interconnecting them vertically so that they behave as a single device. In some cases the stacked IC device may have multiple cores.

In some 3D stacks, through-substrate vias (TSVs) create vertical connections through the body of the semiconductor device. As their name suggests, TSVs are generally substantially vertical interconnects used to make electrical connections through a semiconductor. TSVs may include a conducting core and an insulating sleeve contained in a semiconductor substrate. By using TSV technology, stacked IC devices can pack a great deal of functionality into a small footprint. This TSV technique is sometimes also referred to as TSS (Through Silicon Stacking). TSVs are also referred to as through-silicon vias. With TSVs, critical electrical paths through the device can be drastically shortened, reducing capacitance and resistance and therefore improving power dissipation, and performance.

As die stacks become more complicated and are used more, issues of failure are presented. For 3D chip integration, if a good die is stacked with a bad die, the whole stack would be bad. Ensuring that a die and the stack are good is important. Like all ICs, these 3D stacked ICs are tested for manufacturing defects. Conventional test solutions include boundary scan testing, and include control and observation of special design-for-testability (DFT) features or circuitry.

In a 3D stacked IC, the base die (or bottom die) has external I/O (input/output) pads. The I/O pads of upper tier die are usually not accessible in a stack because they are formed using embedded TSVs or tier to tier connections coupled to TSVs. Although additional I/O pads could be added to the upper tiers to permit external access, it is generally desirable to reduce the number of connection pads, which occupy a large area compared to TSVs, on each tier of the stack. Therefore, scan chain inputs and outputs, used for testing, of each tier in a stack cannot be accessed externally in a 3D stacked IC. In order to apply test patterns to the upper tier dies and to observe the captured responses, it would be desirable to have external access to these scan chains within all tiers. Therefore, there is a need to develop methods and structures to enable such testing of 3D stacked ICs in a more efficient manner.

### SUMMARY

According to one aspect of the present disclosure, an apparatus for testing multiple components of a 3D stacked integrated circuit (IC) is described. The apparatus includes a base component having a scan input pad, a scan output pad, a base scan chain, and a base chain access block. The base chain access block includes a base chain select multiplexor and a base bypass multiplexor. The apparatus further includes a secondary component having a secondary scan chain and a secondary chain access block including a secondary chain select multiplexor and a secondary bypass multiplexor. The secondary chain select multiplexor is configured to receive input directly from the base component and another component. The base and secondary chain access blocks are configured to selectively access the base scan chain and/or the secondary scan chain.

In another aspect, a method of selectively accessing scan chains in multiple tiers of a 3D stacked integrated circuit (IC) is described. The method includes accessing at least one scan chain in one of the tiers by controlling a chain select multiplexor to selectively receive test data from an upper tier or a lower tier.

In a further aspect, an apparatus for selectively accessing scan chains in multiple components of an integrated circuit (IC) is described. The apparatus includes means for multiplexing inputs from an upper component and a lower component to access at least a scan chain in one of the components by selecting a scan chain input from the lower component or a scan chain output from the upper component. The apparatus further includes means for bypassing a scan chain by selecting an output of the multiplexing means or an output of the scan chain.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 is a conceptual diagram of a 3D stacked IC, according to one aspect of the present disclosure.

FIG. 2 is a diagram conceptually illustrating one configuration of a testing apparatus, according to one aspect of the present disclosure.

FIG. 3 is a diagram conceptually illustrating one configuration of a testing apparatus in a 3D stacked IC, according to one aspect of the present disclosure.

FIG. 4 is a table illustrating an exemplary chain access control truth table, according to one aspect of the present disclosure.

FIG. 5 is a block diagram illustrating a method for testing multiple components of a 3D stacked integrated circuit (IC), according to one aspect of the present disclosure.

FIG. 6 is a block diagram showing an exemplary wireless communication system in which the features of the present disclosure may be advantageously employed.

FIG. 7 is a block diagram illustrating a design workstation for circuit, layout, and logic design of a semiconductor component according to one aspect of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

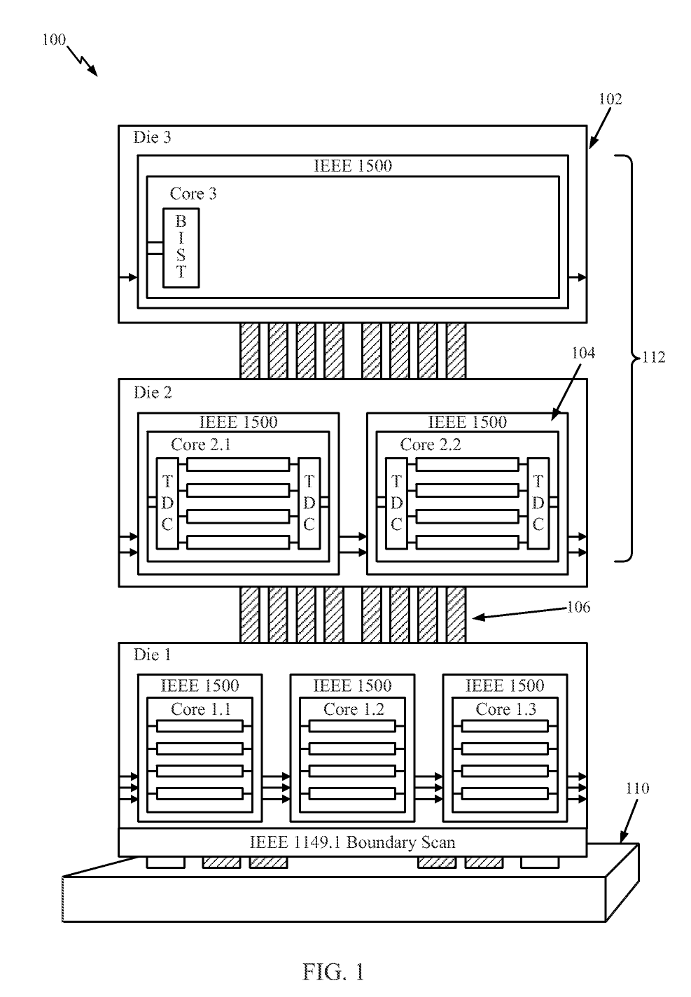

FIG. 1 shows a cross-sectional view illustrating a 3D stacked integrated circuit (IC) package 100. Representatively, the stacked IC package 100 includes a packaging substrate 110, multiple stacked dies 102, and interconnects 106. Each die 102 may also include multiple cores 104. The interconnects 106 may be tier to tier connections coupled to TSVs (not shown) within each die 102. Scan chains are provided in each tier. Aspects of the present disclosure allow for access and testing of the scan chains 112 in the upper tiers 114 of the package 100. In addition, aspects of the disclosure also allow for configuration of internal logic testing as well as testing of the tier to tier interconnects 106. Other configurations of this disclosure further allow communication of this test data. Also, aspects of this disclosure may test multiple cores within a multi core die. Configurations of this disclosure can support single scan chains or multiple scan chains. Furthermore, test data from any tier can be elevated up and down the remaining tiers to individual scan chains.

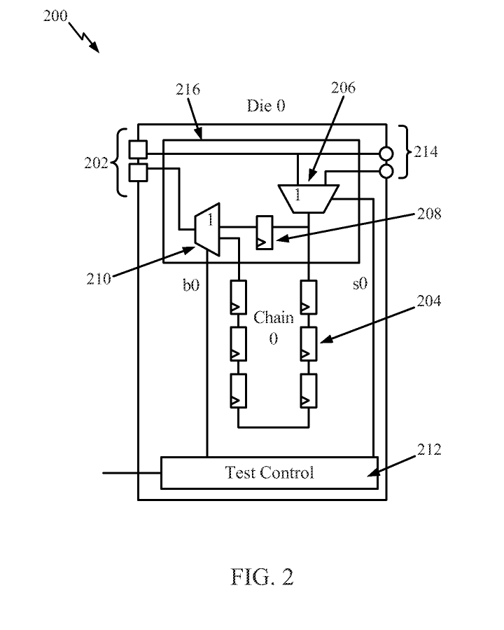

FIG. 2 shows a conceptual view of an exemplary base die 200 with one configuration of a testing apparatus according to the disclosure. The die 200 includes scan chain input and output pads 202 and interconnects 214. Though only two pads are provided in this configuration, it is understood that any number of pads may be present. It is, however, advantageous to use as few pads as possible due to the space occupied by the pads. A die which is not a base die, but is instead an upper tier die, would include interconnects (on both sides if the tier is not the uppermost tier) of the die for coupling to additional dies, omitting the scan chain input and output pads 202.

The I/O pads 202 may be coupled to any control mechanism. This allows a control mechanism to be implemented using any control method, including standard test control methods, such as those complying with IEEE 1149.1 JTAG, IEEE 1149.7, and/or IEEE 1500. In some configurations, the scan chains may be controlled with a common test clock (e.g., TCK for the IEEE 1149.1 test access standard).

The die includes a scan chain 204, which may be selectively activated by configurations of the disclosure. The die further includes a scan chain access block 216. The scan chain access block 216 serves to control whether a scan chain is accessed or bypassed. This functionality is achieved by a scan chain select multiplexor 206, a bypass multiplexor 210, and an optional bypass flop 208, all within the scan chain access block 216.

The die also may include a test control block 212. This test control block contains information regarding the tests themselves, delivering the control signals used to select and access the scan chains. The test control block 212 can be implemented using any standard test interface like those defined in IEEE 1149.1, 1149.7 and/or 1500. The test control block 212 controls the scan chain select multiplexor 206 and the bypass multiplexor 210 with control signals s0 and b0, respectively.

The bypass flop 208 functions to manage timing across the dies, but this flop is optional. The bypass flop 208 couples to the output of the scan chain select multiplexor 206 and to the input of the bypass multiplexor 210. The scan chain select multiplexor 206 functions to select the scan input from a lower die (or the I/O pads 202) or scan chain output from an upper die. The chain select multiplexor output is coupled to an input of the scan chain 204. The bypass multiplexor 210 functions to select the output of the scan chain select multiplexor 206 (and optional bypass flop 208) or output of the scan chain 204. The output of the bypass multiplexor 210 is coupled to the I/O pads 202 (or lower tier die if the die is an upper tier die.).

The scan chain access block 216 enables accessing and selecting of the scan chain for the die or core in which it is instantiated, or bypassing the scan chain for the die or core, concatenating the chain above to the chain on the die or core, concatenating the chain to the chain below, or any combination of the above. The bypass mechanism allows access to individual scan chains on a die or core or a subset of die or core scan chains for interconnect tests.

It is important to note that although FIG. 2 only depicts one scan chain, there may be multiple scan chains for each die. With multiple scan chains, the test control block would remain the same, however, multiple bypass and chain select (bn and sn) bits would be employed to control each scan chain access block.

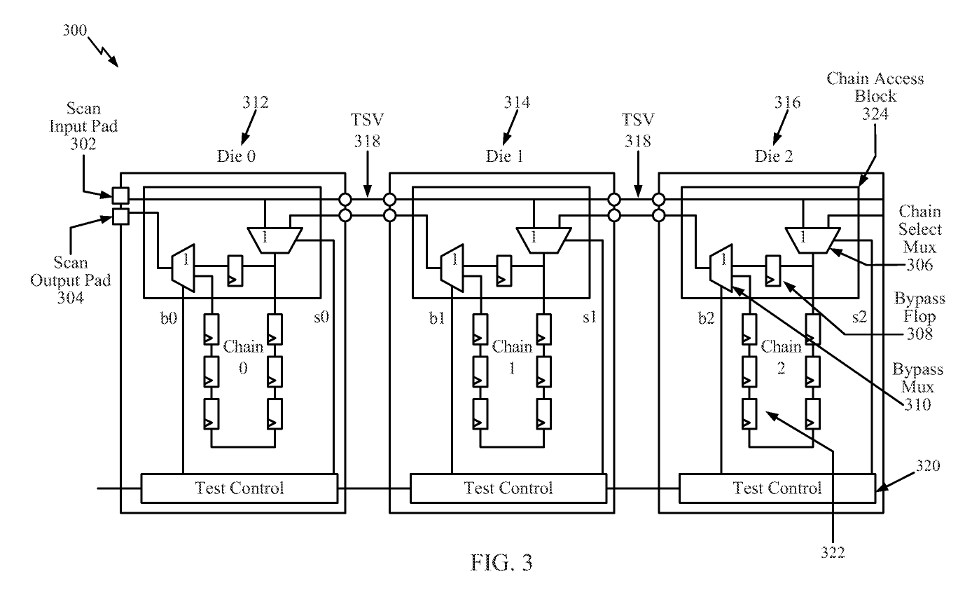

FIG. 3 illustrates a conceptual view of three dies 312, 314, 316 stacked in a 3D stacked IC 300. For simplicity, some of the similar components located in multiple dies have not been separately labeled. Die0 312 of FIG. 3 is similar to the die 200 of FIG. 2 and is considered the base or bottom die in this configuration. As with the die of FIG. 2, die0 has scan input 302 and output 304 pads for test control inputs and outputs. Die0 312, die1 314, and die2 316 are interconnected using TSVs and tier to tier connections 318. Each die contains a scan chain: Chain 0, Chain 1, and Chain 2 322. As discussed in relation to FIG. 2, each die contains a scan chain access block 324 and a test control block 320. The middle tier die (die1) 314 includes two TSV ports 318 (for each scan chain) coupled to the upper die 316, and two TSV ports 318 (for each scan chain) coupled to the lower die 312. As discussed previously, for the bottom die 312 these two ports couple to scan input 302 and scan output 304 pads. The upper tier die (die2) 316 includes two TSV ports 318 (for each scan chain) coupled to the middle die 314.

Each chain access block 324 has a chain select multiplexor 306 and a bypass multiplexor 310, interconnected as described in relation to FIG. 2. Please note that here one chain is shown, however, there may be multiple scan chains for each die. An optional bypass flop 308 can also be included. A test control block 320 is also included in each die 312, 314, 316. Each test control block 320 sends control signals b0, b1, b2 to the bypass multiplexor 310 of each die 312, 314, 316, respectively. Each test control block 320 sends control signals s0, s1, s2 to the chain select multiplexor 306 of each die 312, 314, 316, respectively.

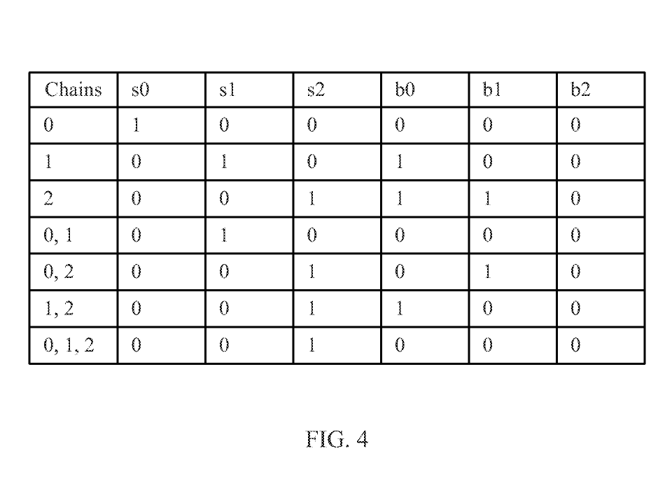

An example of how the bypass and concatenation features of the chain access blocks would function is now described with respect to the table of FIG. 4 and the dies of FIG. 3. The table of FIG. 4 shows combinations of scan chains tested in relation to the different control signals output by the test control block 320. The first column of the table lists the chains tested in that instance. The remaining columns list the control signals sent by the test control block of each die, such that s0, s1, s2 refer to the control signals sent to the chain select multiplexor 306 of each die 312, 314, 316, respectively, and b0, b1, b2 refer to the control signals sent to the bypass multiplexor 310 of each die 312, 314, 316, respectively.

A high (1) chain select multiplexor control signal (s0, s1, s2) causes the respective multiplexor to accept the scan input from the lower die and execute the respective scan chain testing. A low (0) control signal causes the multiplexor to instead accept the scan chain output from an upper tier, thereby causing that tier to bypass executing the test input from the lower die. A high (1) bypass multiplexor control signal (b0, b1, b2) causes the bypass multiplexor to accept the input from the bypass flop (or chain select multiplexor if no bypass flop is provided), thereby bypassing the scan chain of that respective tier. A low (0) control signal, however, allows the bypass multiplexor to accept the input from the scan chain.

For example, if testing only scan chain 1 is desired, as in row 2 of FIG. 4, test data is input via the scan input pad 302 of die0 312. The test control block of die 0 312 sends a low control signal s0 to the chain select multiplexor. This causes the chain select multiplexor of die0 312 to select the scan chain output of an upper tier rather than accepting the input from the scan input pad, thereby skipping or bypassing the scan chain of die0 312 for the time being. The test information from the scan input progresses via the TSVs/tier to tier connections 318 to die1 314. The test control block of die1 314 sends a 1 as the chain select multiplexor control signal s1, causing the multiplexor to accept the input from the lower die and execute the scan chain testing. The bypass multiplexor of die1 314 receives a control signal b1 of 0 from the test control block, causing the multiplexor to accept the input from the scan chain. This data then is transmitted via the TSVs/tier to tier connections 318 back to die0 312, where the chain select multiplexor accepts the input from the upper tier (die 1) and executes scan chain 0. The bypass multiplexor of die0 312, which has received a high (1) test control signal b0, bypasses the scan chain 0 data and instead outputs only the scan chain data of die1 314 to the scan output pad 304. The scan chain of die2 316 is never executed as the multiplexor is set to accept input from an upper tier, which is not in place, and the data would not have been communicated through die1 314 because the chain select multiplexor of die1 314 was set to accept the scan input of a lower tier, not an upper tier.

In another example, if testing scan chain 0 and 2 is desired, the control, signal s2 to the chain select multiplexor of die2 316 would be 1 and the control signal b2 to the bypass multiplexor b1 of die1 314 would be 1, while the outputs of the control signals for the remaining multiplexors would all be 0, as shown in row 5 of FIG. 4.

In this example, the chain select multiplexors of die0 312 and die1 314 both receive low or 0 control signals s0, s1 from their respective test control blocks. This causes the scan chain multiplexors of die0 312 and die1 314 to accept the test data from an upper tier not the lower tier, thereby the test data input from the scan input pad 302 skips these dies, traversing the TSVs/tier to tier connections 318 to die2 316. The scan chain multiplexor 306 of die2 316 receives a high control signal s2 from the test control block 320, accepting the test data from the lower tier and transmitting it to scan chain 2. The bypass multiplexor 310 of die2 316 receives a control signal b2 of 0, causing the multiplexor to transmit the data from the scan chain 2. This data traverses the TSV/tier to tier connection 318 to die 314 where the data is accepted by the scan chain select multiplexor and output to the scan chain 1 and bypass flop. The bypass multiplexor of die1 314 received a high control signal b1, which causes the multiplexor to bypass the scan chain 1 of die 1, accepting the data from the bypass flop, and outputting this data through the TSVs/tier to tier connection 318 to die0 312. In die0, the scan chain multiplexor accepts the upper tier data and outputs this data to the scan chain 0 and bypass flop. In die0 312 the bypass multiplexor has received a low (0) control signal b0 from the test control block., causing the bypass multiplexor not to bypass the scan chain 0 but instead accept the data and output it to the scan output pad 304. Therefore, test data was executed and output from the scan chains of die0 312 and die2 316. Additional examples of control signals and resulting tested scan chains are shown in the remainder of the rows of FIG. 4.

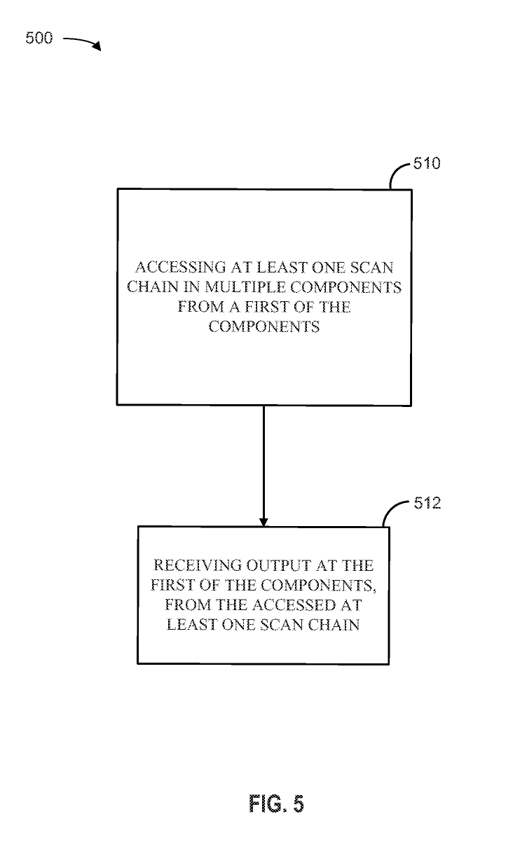

FIG. 5 illustrates a method 500 for accessing scan chains of a 3D stacked IC. In block 510, a control method accesses at least one scan chain of several components (e.g., tiers or cores) from a first one of the components (e.g., tiers or cores). In block 512, the control method optionally receives output at the first of the components (e.g., tiers or cores), from the accessed scan chain(s). These methods may be carried out by the structures and components described above in relation to FIGS. 2 and 3.

In one configuration, an apparatus has means for accessing and means for bypassing. In one aspect, the accessing means may be the chain select multiplexor 206, 306 configured to perform the functions recited by the accessing means. The apparatus is also configured to include a means for bypassing. In one aspect, the bypassing means may be the bypass multiplexor 210, 310 configured to perform the functions recited by the bypass means. In another aspect, the aforementioned means may be any module or any apparatus configured to perform the functions recited by the aforementioned means.

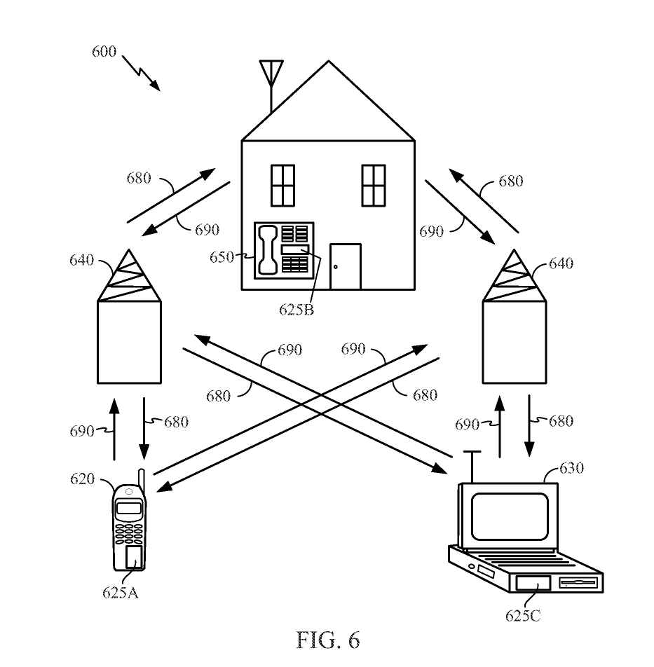

FIG. 6 shows an exemplary wireless communication system 600 in which a configuration of the disclosed calibration method may be advantageously employed. For purposes of illustration, FIG. 6 shows three remote units 620, 630, and 650 and two base stations 640. It will be recognized that wireless communication systems may have many more remote units and base stations. Remote units 620, 630, and 650 include multiple component testing circuitry 625A, 625B, and 625C, respectively. FIG. 6 shows forward link signals 680 from the base stations 640 and the remote units 620, 630, and 650 and reverse link signals 690 from the remote units 620, 630, and 650 to base stations 640.

In FIG. 6, the remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates remote units, which may employ testing circuitry according to the teachings of the disclosure, the disclosure is not limited to these exemplary illustrated units. For instance, testing circuitry according to configurations of the present disclosure may be suitably employed in any device.

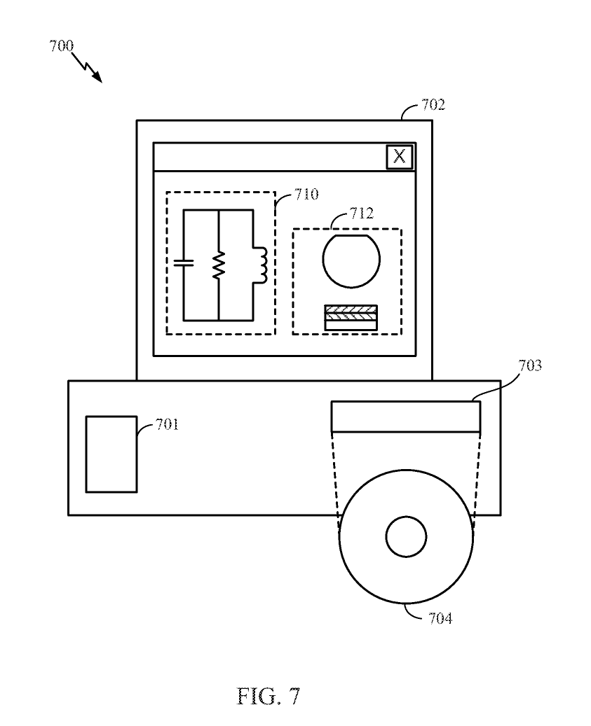

FIG. 7 is a block diagram illustrating a design workstation used for circuit, layout, and logic design of a semiconductor component, such as the testing circuitry disclosed above. A design workstation 700 includes a hard disk 701 containing operating system software, support files, and design software such as Cadence or OrCAD. The design workstation 700 also includes a display 702 to facilitate design of a circuit 710 or a semiconductor component 712 such as the testing circuitry. A storage medium 704 is provided for tangibly storing the circuit design 710 or the semiconductor component 712. The circuit design 710 or the semiconductor component 712 may be stored on the storage medium 704 in a file format such as GDSII or GERBER. The storage medium 704 may be a CD-ROM, DVD, hard disk, flash memory, or other appropriate device. Furthermore, the design workstation 700 includes a drive apparatus 703 for accepting input from or writing output to the storage medium 704.

Data recorded on the storage medium 704 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 704 facilitates the design of the circuit design 710 or the semiconductor component 712 by decreasing the number of processes for designing semiconductor wafers.

Although specific circuitry has been set forth, it will be appreciated by those skilled in the art that not all of the disclosed circuitry is required to practice the disclosed configurations. Moreover, certain well known circuits have not been described, to maintain focus on the disclosure. Similarly, although the relative terms “upper” and “lower” are used, these terms are non-limiting. For example if a device is rotated by 90 degrees the terms “upper” and “lower” would refer to “left most” and “right most” portions.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the disclosure herein may be embodied directly in hardware, in a software module executed by a processor, or in a combination of the two.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus for testing multiple components of a 3D stacked integrated circuit (IC), comprising:
a base component having a scan input pad, a scan output pad, a base scan chain, and a base chain access block including a base chain select multiplexor and a base bypass multiplexor; and
a secondary component having a secondary scan chain and a secondary chain access block including a secondary chain select multiplexor and a secondary bypass multiplexor, the secondary chain select multiplexor configured to receive input directly from the base component and another component, the base and secondary chain access blocks being configured to selectively access the base scan chain and/or the secondary scan chain.

2. The apparatus of claim 1, in which the components comprise tiers of the 3D stacked IC, at least one of the tiers comprising through substrate vias (TSVs).

3. The apparatus of claim 1, in which the components comprise cores of a multi core die.

4. The apparatus of claim 1, in which the scan input pad and scan output pad are configured to selectively read and write to the base and/or secondary scan chain.

5. The apparatus of claim 1, further comprising a test controller within at least one of the components and coupled to the base and secondary chain access blocks, the test controller configured to communicate with the base and secondary chain access block to enable the selective access of the base and secondary scan chains.

6. The apparatus of claim 1, in which the base chain select multiplexor is configured to directly receive input from the scan input pad and the secondary component.

7. The apparatus of claim 1, in which the base bypass multiplexor is configured to directly receive input from the base chain select multiplexor and the base scan chain.

8. The apparatus of claim 1, in which the secondary bypass multiplexor is configured to directly receive input from the secondary chain select multiplexor and the secondary scan chain.

9. The apparatus of claim 1, in which the base chain access block further comprises a base bypass flop and the secondary chain access block further comprises a secondary bypass flop, the base and secondary bypass flops configured to manage timing across the components.

10. The apparatus of claim 9, in which
the base bypass flop is coupled to the base chain select multiplexor and the base bypass multiplexor,
the base bypass multiplexor is configured to directly receive input from the base bypass flop and the base scan chain;
the secondary bypass flop is coupled to the secondary chain select multiplexor and the secondary bypass multiplexor; and
the secondary bypass multiplexor is configured to directly receive input from the secondary bypass flop and the secondary scan chain.

11. The apparatus of claim 1, integrated into a mobile phone, a set top box, a music player, a video player, an entertainment unit, a navigation device, a computer, a hand-held personal communication systems (PCS) unit, a portable data unit, and/or a fixed location data unit.

12. A method of selectively accessing scan chains in multiple tiers of a 3D stacked integrated circuit (IC), comprising:
accessing at least one scan chain in one of the tiers by controlling a chain select multiplexor to selectively receive test data from an upper tier or a lower tier.

13. The method of claim 12, further comprising controlling a bypass multiplexor to either receive output from the accessed at least one scan chain, or the chain select multiplexor.

14. The method of claim 12, further comprising integrating the IC into a mobile phone, a set top box, a music player, a video player, an entertainment unit, a navigation device, a computer, a hand-held personal communication systems (PCS) unit, a portable data unit, and/or a fixed location data unit.

15. An apparatus for selectively accessing scan chains in multiple components of an integrated circuit (IC), comprising:
means for multiplexing inputs from an upper component and a lower component to access at least a scan chain in one of the components by selecting a scan chain input from the lower component or a scan chain output from the upper component; and
means for bypassing a scan chain by selecting an output of the multiplexing means or an output of the scan chain.

16. The apparatus of claim 15, in which the components comprise tiers of the 3D stacked IC, at least one of the tiers comprising through substrate vias (TSVs).

17. The apparatus of claim 15, in which the components comprise cores of a multi core die.

18. The apparatus of claim 15, integrated into a mobile phone, a set top box, a music player, a video player, an entertainment unit, a navigation device, a computer, a hand-held personal communication systems (PCS) unit, a portable data unit, and/or a fixed location data unit.

19. A method of selectively accessing scan chains in multiple tiers of an integrated circuit (IC), comprising the step of:
accessing at least one scan chain in one of the tiers by controlling a chain select multiplexor to selectively receive test data from an upper tier or a lower tier.

20. The method of claim 19, further comprising the step of integrating the IC into a mobile phone, a set top box, a music player, a video player, an entertainment unit, a navigation device, a computer, a hand-held personal communication systems (PCS) unit, a portable data unit, and/or a fixed location data unit.
